(19) United States
(12) Patent Application Publication
(10) Pub. No.: US 2006/0091467 A1
(43) Pub. Date: May 4, 2006

(54) Resonant tunneling device using metal oxide semiconductor processing

(76) Inventors: Brian S. Doyle, Portland, OR (US); Suman Datta, Beaverton, OR (US); Justin Brask, Portland, OR (US); Jack Kavalieros, Portland, OR (US); Amlan Majumdar, Portland, OR (US); Marko Radosavljevic, Beaverton, OR (US); Robert S. Chan, Beaverton, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/977,261

(22) Filed: Oct. 29, 2004

(51) Int. Cl. H01L 29/94

(52) U.S. Cl. 257/368

(57) ABSTRACT

An embodiment of the present invention is a technique to fabricate a semiconductor device having low off state leakage current. A gate structure of a first device is formed on a substrate layer having a hardmask. A channel is formed underneath the gate structure having a width to support the gate structure. An oxide or a dielectric layer is deposited on the substrate layer. A doped polysilicon layer is deposited on the oxide layer. A recessed junction area is formed on the doped polysilicon layer between the first device and an adjacent device.

### FIELD OF THE INVENTION

Embodiments of the invention relate to the field of semiconductors, and more specifically, to semiconductor fabrication processes.

### DESCRIPTION OF RELATED ART

Demands for high performance processors have presented many challenges to semiconductor device fabrication technology. As gate lengths reduce, the problem of off-state leakage becomes more and more severe. At each generation of technology, the allowable transistor off-state leakage current is increased by a factor of three over the previous generation. It is important to be able to control this parasitic off-state leakage to reduce power consumption and other undesirable effects. The leakage arises from the diffusion over the barrier between the source and the channel, which is primarily determined by the temperature of the transistor.

Existing techniques for controlling off-state leakage have a number of disadvantages. In one technique, the channel region is aggressively doped with either flat-well profiles or halo dopings. Another technique aims at reducing the amount of diffusion that the dopants are subjected to during the thermal processing stages. These techniques, however, are not efficient and require complex processing operations.

### BRIEF DESCRIPTION OF THE DRAWINGS

The embodiments of invention may best be understood by referring to the following description and accompanying drawings that are used to illustrate embodiments of the invention. In the drawings:

FIG. 1 is a diagram illustrating a device in which one embodiment of the invention can be practiced.

FIG. 2 is a diagram illustrating the effect of the tunnel barriers according to one embodiment of the invention.

FIG. 3A is a diagram illustrating forming a gate structure according to one embodiment of the invention.

FIG. 3B is a diagram illustrating forming a channel according to one embodiment of the invention.

FIG. 3C is a diagram illustrating depositing an oxide/dielectric layer according to one embodiment of the invention.

FIG. 3D is a diagram illustrating depositing a doped polysilicon layer according to one embodiment of the invention.

FIG. 3E is a diagram illustrating forming a recessed junction area according to one embodiment of the invention.

FIG. 3F is a diagram illustrating depositing resist according to one embodiment of the invention.

FIG. 3G is a diagram illustrating etching the doped polysilicon layer according to one embodiment of the invention.

FIG. 3H is a diagram illustrating stripping the resist according to one embodiment of the invention.

FIG. 4 is a flowchart illustrating a process to fabricate the device according to one embodiment of the invention.

### DESCRIPTION

An embodiment of the present invention is a technique to fabricate a semiconductor device having low off state leakage current. A gate structure of a first device is formed on a substrate layer having a hardmask. A channel is formed underneath the gate structure having a width to support the gate structure. An oxide or a dielectric layer is deposited on the substrate layer. A doped polysilicon layer is deposited on the oxide layer. A recessed junction area is formed on the doped polysilicon layer between the first device and an adjacent device.

In the following description, numerous specific details are set forth. However, it is understood that embodiments of the invention may be practiced without these specific details. In other instances, well-known circuits, structures, and techniques have not been shown to avoid obscuring the understanding of this description.

One embodiment of the invention may be described as a process which is usually depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed. A process may correspond to a method, a program, a procedure, a method of manufacturing or fabrication, etc.

An embodiment of the invention is a method to fabricate a resonant tunneling transistor using conventional metal oxide semiconductor (MOS) processing techniques. The technique uses an epitaxial tip to undercut the silicon beneath the gate and creates a channel or a column of silicon having a width of less than 10 nanometers. This results in a quantum confinement of the channel region. By subsequent light oxidation of the etched regions, the source and the drain regions are separated by tunnel barriers from the channel. Using the gate to alter the Fermi energy levels, the conditions of resonant tunneling are controlled by the gate potential. The junctions are formed by doped polysilicon deposition and etchback.

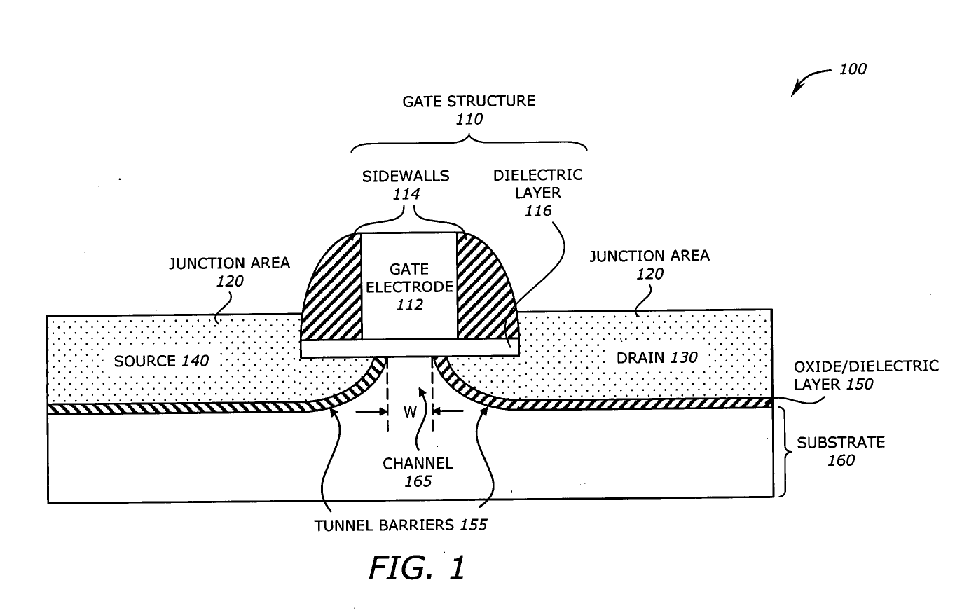

FIG. 1 is a diagram illustrating a device 100 in which one embodiment of the invention can be practiced. The device 100 includes a gate structure 110, a junction area 120, an oxide or dielectric layer 150, and a substrate 165. The device 100 is fabricated using conventional metal oxide semiconductor (MOS) process technology. It is a typical MOS field effect transistor (FET) device with enhanced performance for reduced gate channel lengths.

The gate structure 110 includes a gate electrode 112, two sidewalls 114, and a dielectric layer 116. The gate electrode 112 is typically made of polysilicon. The two sidewalls 114 are formed on the opposite sides of the gate electrode 112. The gate electrode 112 and the two sidewalls 114 are formed on the dielectric layer 116.

The junction area 120 is formed around the gate structure 110 to define the junction regions. The junction area 120 includes a drain region 130 and a source region 140 on both sides of the gate structure 110. The drain and source regions 130 and 140 are typically formed from a doped polysilicon layer.

The oxide or dielectric layer 150 is formed underneath the source and drain regions 130 and 140. The oxide or dielectric layer 150 has a thickness of approximately three to seven Angstroms. It is undercut toward the inside of the gate structure 110 to form a recessed area on each of the source and drain regions 130 and 140. These recessed areas form tunnel barriers 155 underneath the gate structure 110 and the junction area 120. The oxide or dielectric layer 150 defines a channel, a post, or a column 165 with a width W to support the gate structure 110. The width W is typically less than 10 nanometers.

The substrate layer 160 is underneath the oxide or dielectric layer 150. It is etched to form the channel 165. It is typically made of silicon.

The device 100 is capable of exhibiting electrical characteristics similar to a resonant tunneling transistor. The tunnel barriers 155 and the channel 165 provide a potential energy characteristic with respect to distance to the device 100. This potential energy characteristic allows the device 100 to have very little leakage current in off state. An off state is the state where the device 100 does not conduct current. An on state is the state where the device 100 conducts current.

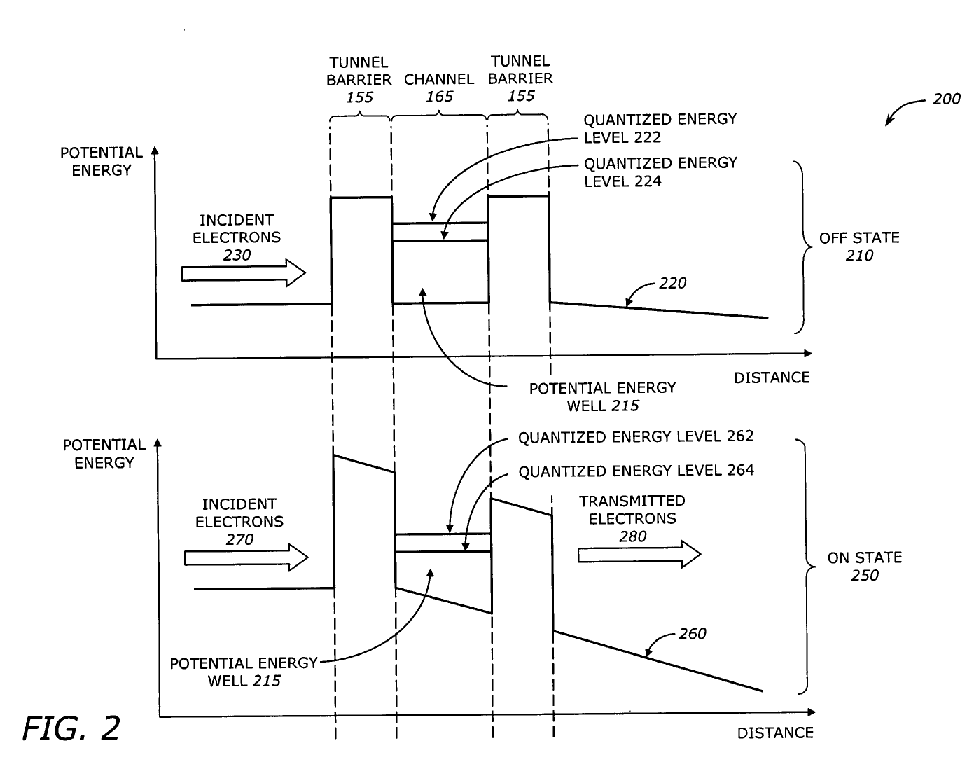

FIG. 2 is a diagram illustrating the effect of the tunnel barriers according to one embodiment of the invention. The effect of the tunnel barriers is illustrated for an off state 210 and an on state 250.

In the off state 210, the device 100 exhibits a potential energy characteristic 220. The characteristic 220 has a potential energy well 215 that corresponds to the channel 165 of the device 100. On both sides of the well 215 are the two tunnel barriers corresponding to the tunnel barriers 155 of the device 100. In this illustrative example, the current is shown as the movement of the electrons from the source region 140 to the drain region 130 via incident electrons 230. The energy levels are quantized into several discrete levels such as levels 222 and 224.

In the off state where the gate voltage V_{g} is zero, the energy levels 222 and 224 in the channel 165 are not aligned with the incident electrons 230. The incident electrons 230 are essentially blocked from going through the channel 165, resulting in minimal current leakage.

In the on state 250 where the gate voltage V_{g} is greater than a threshold voltage Vₜ, the device 100 exhibits a potential energy characteristic 260. This characteristic 260 is lowered toward the drain region. When there is a bias voltage applied to the gate, the quantized energy levels 262 and 264 are lower than the levels 222 and 224 such that they are aligned with the incident electrons 270. The Fermi energy level of the incident electrons 270 may provide a resonant condition during which the charge carriers can tunnel through the tunnel barriers. The incident electrons 270 move through the channel 165 to become transmitted electrons 280 in the drain region 130. The transmitted electrons 280 represent a significant current flow in the on state.

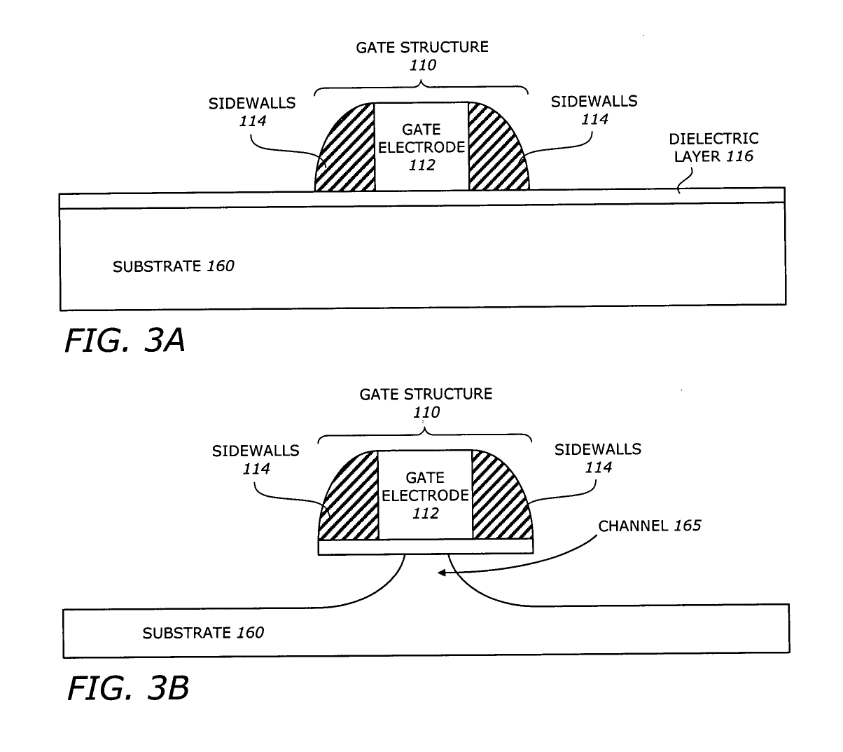

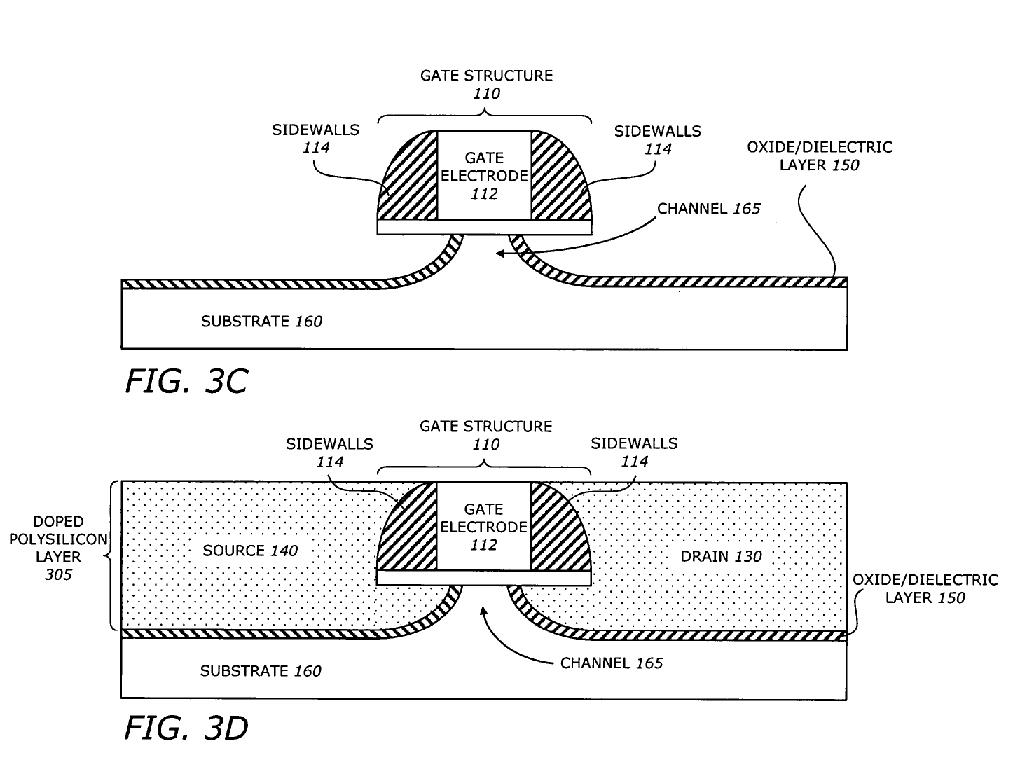

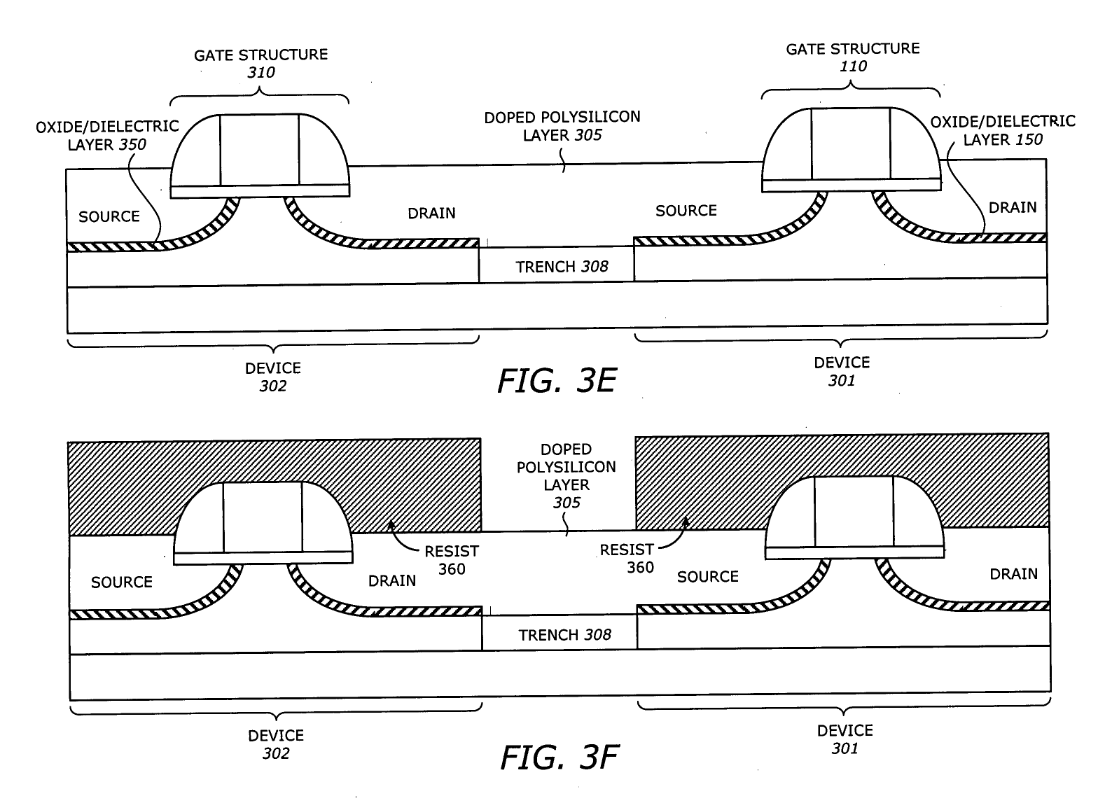

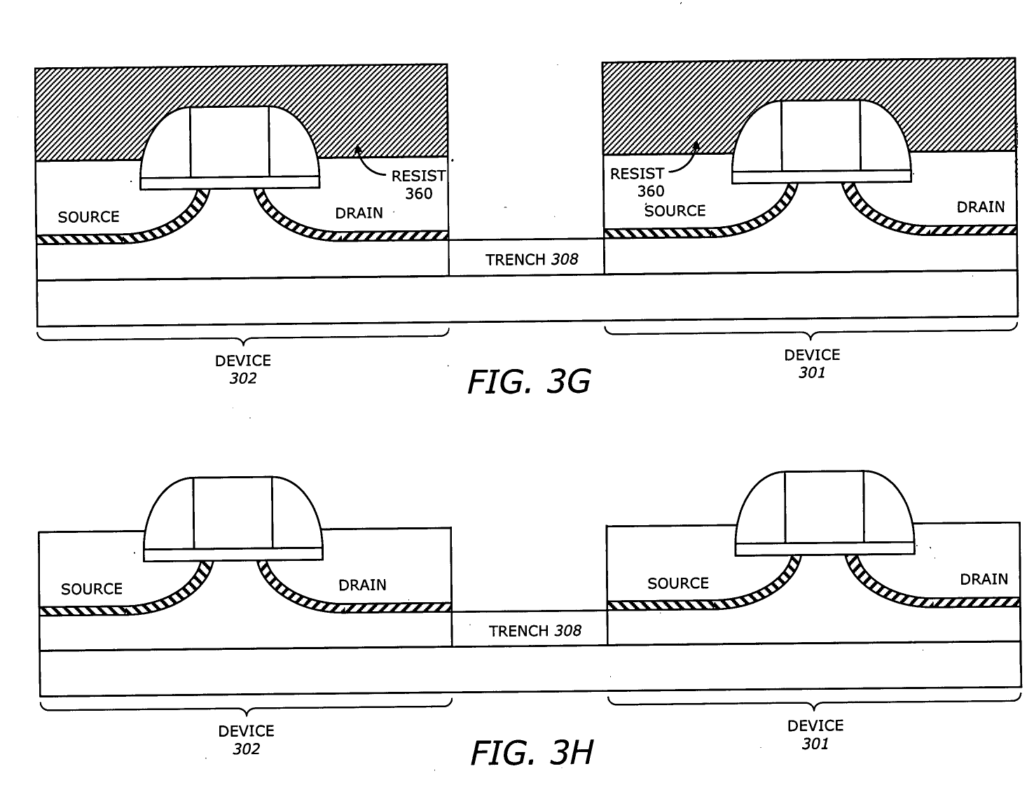

The channel 165, in essence, modulates the energy levels in the potential energy well 215 when a voltage is applied such that there is a low leakage current flowing in an off state, and significant current flowing in an on state. By controlling or adjusting the width W of the channel 165 and/or the thickness of the oxide/dielectric layer 150, the amount of current leakage may be accurately controlled and minimized. The device 100 may be fabricated using conventional MOS processing as shown from FIGS. 3A through 3H.

FIG. 3A is a diagram illustrating forming the gate structure 110 according to one embodiment of the invention. The gate structure 110 includes the gate electrode 112, two sidewalls 114, and a dielectric layer 116. The dielectric layer 116 is on the substrate layer 160. The substrate layer is typically silicon. The process to form the gate structure 110 may be any MOS processing method. A hardmask remains on the polysilicon.

FIG. 3B is a diagram illustrating forming the channel 165 according to one embodiment of the invention. The substrate layer 160 is etched to undercut the gate area on both sides to form the channel 165 having a width less than 10 nanometers. The channel 165 supports the gate structure 110 at approximately the middle.

FIG. 3C is a diagram illustrating depositing an oxide/dielectric layer according to one embodiment of the invention. The silicon is then subjected to oxidation. An oxide layer 150 is formed on the substrate layer 160 having a thickness of approximately five Angstroms, typically between three and seven Angstroms. Alternatively, a dielectric layer 150 with high dielectric constant may be deposited on the substrate layer 160. The recessed areas on both sides of the channel 165 form two tunnel barriers 155.

FIG. 3D is a diagram illustrating depositing a doped polysilicon layer according to one embodiment of the invention. A doped polysilicon layer 310 is deposited on the oxide/dielectric layer 150 and around the gate structure 110. This may be done by depositing undoped polysilicon layer and using implant to dope the polysilicon. This may also be polysilicon layer that eventually is completely silicided.

FIG. 3E is a diagram illustrating forming a recessed junction area according to one embodiment of the invention. In this illustrative example, two adjacent devices in the same wafer are shown: device 301 and device 302. The two devices are separated by a trench 308. The device 302 has a gate structure 310 and an oxide/dielectric layer 350 similar to the gate structure 110 and the oxide/dielectric layer 150 in device 301. The wafer is polished to the gate hardmask level. The isolation areas are cleared of the polysilicon by reusing the diffusion mask if necessary. A reactive ion etch (RIE) silicon etch is then performed. During this etching, the gate polysilicon remains covered with the hardmask. The polysilicon line between the two devices may cause shorting. The two devices therefore need to be isolated. The isolation areas are cleared of the polysilicon by reusing the diffusion mask if necessary.

FIG. 3F is a diagram illustrating depositing resist according to one embodiment of the invention. A resist 360 is deposited on the doped polysilicon layer 310. The trench mask may be reused to deposit and develop the resist 360.

FIG. 3G is a diagram illustrating etching the doped polysilicon layer according to one embodiment of the invention. The doped polysilicon layer 310 is then etched between the two devices 301 and 302. The two devices are now electrically isolated.

FIG. 3H is a diagram illustrating stripping the resist according to one embodiment of the invention. The resist 360 is then stripped off the wafer. The gate hardmask is then removed.

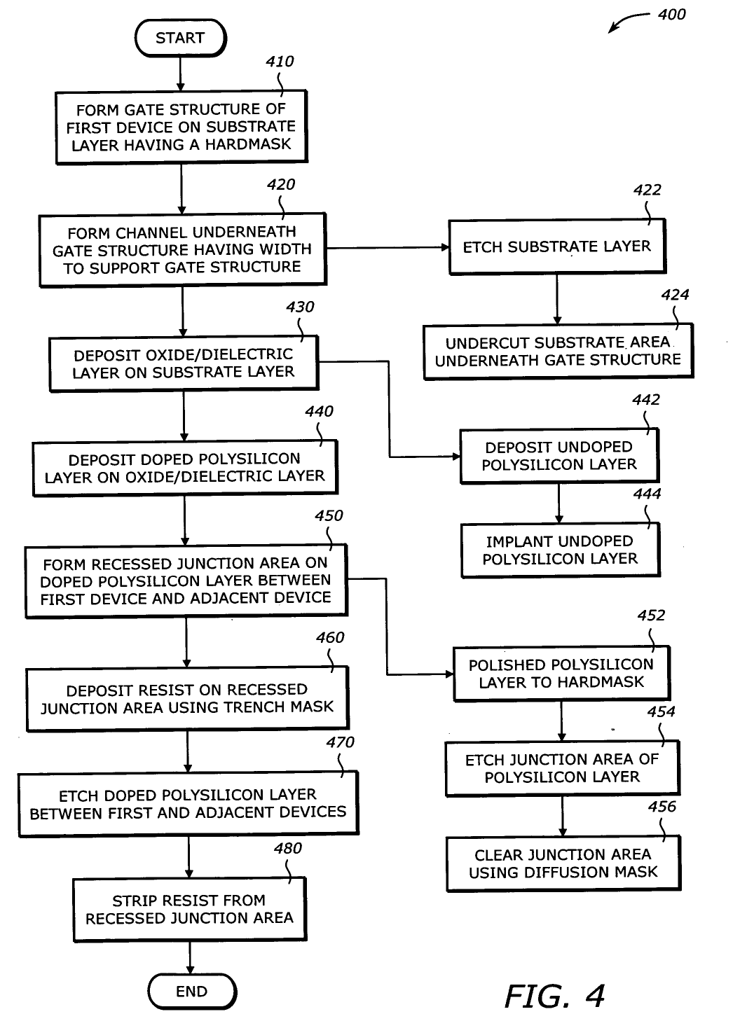

FIG. 4 is a flowchart illustrating a process 400 to fabricate the device according to one embodiment of the invention.

Upon START, the process 400 forms a gate structure of a first device on a substrate layer having a hardmask (Block 410). This can be performed using conventional MOS process, corresponding to FIG. 3A Next, the process 400 forms a channel underneath the gate structure having a width to support the gate structure (Block 420) as shown in FIG. 3B. This can be done by etching the substrate layer (Block 422) and undercutting the substrate area underneath the gate structure (Block 424). Then, the process 400 deposits an oxide or dielectric layer on the substrate layer (Block 430) as shown in FIG. 3C. Next, the process 400 deposits a doped polysilicon layer on the oxide/dielectric layer (Block 440) as shown in FIG. 3D. This can be done by depositing an undoped polysilicon layer (Block 442) and implanting the undoped polysilicon layer (Block 444). Then, the process 400 forms a recessed junction area on the doped polysilicon layer between the first device and an adjacent device (Block 450). This can be performed by polishing the doped polysilicon layer to the hardmask level (Block 452), etching the junction area of the doped polysilicon layer (Block 454), and clearing the junction area using a diffusion mask if necessary (Block 456).

Then, the process 400 deposits a resist on the recessed junction area using a trench mask (Block 460) as shown in FIG. 3F. Next, the process 400 etches the doped polysilicon layer between the first and adjacent devices (Block 470) as shown in FIG. 3G. Then, the process 400 strips the resist from the recessed junction area (Block 480) as shown in FIG. 3H and is then terminated.

While the invention has been described in terms of several embodiments, those of ordinary skill in the art will recognize that the invention is not limited to the embodiments described, but can be practiced with modification and alteration within the spirit and scope of the appended claims. The description is thus to be regarded as illustrative instead of limiting.

1. A method comprising:
forming a gate structure of a first device on a substrate layer having a hardmask;
forming a channel underneath the gate structure having a width to support the gate structure;
depositing an oxide or a dielectric layer on the substrate layer;
depositing a doped polysilicon layer on the oxide layer; and
forming a recessed junction area on the doped polysilicon layer between the first device and an adjacent device.

2. The method of claim 1 wherein forming the channel comprises:
etching the substrate layer; and
undercutting a substrate area underneath the gate structure, the undercut substrate area forming the channel.

3. The method of claim 1 wherein depositing the doped polysilicon layer comprises:
depositing an undoped polysilicon layer; and
implanting the undoped polysilicon layer to form the doped silicon layer.

4. The method of claim 1 wherein forming the recessed junction area comprises:
polishing the polysilicon layer to the hardmask; and
etching a junction area of the polysilicon layer to form the recessed junction area.

5. The method of claim 4 wherein forming the recessed junction area comprises: clearing the junction area using a diffusion mask.

6. The method of claim 1 further comprising:
depositing resist on the recessed junction area using a trench mask between the first device and the adjacent device;
etching the doped polysilicon layer between the first device and the adjacent device; and
stripping the resist from the recessed junction area.

7. The method of claim 1 wherein the width is less than 10 nanometers.

8. The method of claim 1 wherein the oxide or dielectric layer has a thickness ranging between three to seven Angstroms.

9. A device comprising:
a gate structure;
a junction area formed around the gate structure;
an oxide or dielectric layer forming tunnel barriers underneath the gate structure and the junction area, the oxide or dielectric layer defining a channel with a width to support the gate structure; and
a substrate layer underneath the oxide or dielectric layer, the substrate layer being etched to form the channel.

10. The device of claim 9 wherein the width of the channel is less than 10 nanometers.

11. The device of claim 9 wherein the oxide or dielectric layer has a thickness between three to seven Angstroms.

12. The device of claim 9 wherein the dielectric layer has a high dielectric constant.

13. The device of claim 9 wherein the substrate layer is silicon.

14. The device of claim 9 wherein the junction area includes a source region and a drain region.

15. The device of claim 14 wherein the tunnel barriers correspond to recessed areas in the source and drain regions underneath the gate structure.

16. A device comprising:
a substrate etched to form a channel having a width and supporting a gate;
an oxide or dielectric layer on the substrate; and
a junction region having a source and a drain on the oxide or dielectric layer, the source and the drain defining two tunnel barriers on two sides of the channel, the channel modulating energy levels when a voltage is applied such that there is a low leakage current flowing in an off state.

17. The device of claim 16 wherein the width of the channel is less than 10 nanometers.

18. The device of claim 16 wherein the oxide or dielectric layer has a thickness between three to seven Angstroms.

19. The device of claim 16 wherein the dielectric layer has a high dielectric constant.

20. The device of claim 16 wherein the substrate layer is silicon.

21. The device of claim 16 wherein the tunnel barriers correspond to recessed areas in the source and the drain underneath the gate structure.
